(19) United States
(12) Patent Application Publication
(10) Pub. No.: US 2021/0285104 A1
(43) Pub. Date: Sep. 16, 2021

(54) CERAMIC SHOWER HEAD AND CHEMICAL VAPOR DEPOSITION DEVICE INCLUDING SAME

(71) Applicant: KSM COMPONENT CO., LTD., Gimpo-si, Gyeonggi-do (KR)

(72) Inventor: Joo Hwan KIM, Gimpo-si (KR)

(73) Assignee: KSM COMPONENT CO., LTD., Gimpo-si, Gyeonggi-do (KR)

(21) Appl. No.: 17/258,071

(22) PCT Filed: Jul. 3, 2019
(86) PCT No.: PCT/KR2019/008156

§ 371 Date: Jan. 5, 2021

(30) Foreign Application Priority Data
Jul. 6, 2018 (KR) 10-2018-0078612

(51) Int. Cl. C23C 16/455; H01J 37/32; C23C 16/505

(52) U.S. Cl. CPC C23C 16/45565; H01J 37/3244; H01J 2237/3321; C23C 16/505; H01J 37/32082

(57) ABSTRACT

A shower head for a chemical vapor deposition system and a chemical vapor deposition device including the shower head are disclosed. The shower head includes a chamber; a process gas inlet for the chamber; a second gas distributor plate provided at the bottom of the chamber; and a first gas distributor plate stacked on the upper surface of the second gas distributor plate, wherein the first gas distributor plate includes multiple gas distribution holes, the second gas distributor plate includes multiple gas injection holes, and a distribution channel is arranged at the boundary surface between the first gas distributor plate and the second gas distributor plate so as to distribute a process gas, introduced through each gas distribution hole of the first gas distributor plate, to 2 to 8 gas injection holes of the second gas distributor plate.

### TECHNICAL FIELD

The present invention relates to a ceramic shower head and a chemical vapor deposition (CVD) device including the same.

### BACKGROUND ART

In general, a shower head refers to a gas injection device used in a chemical vapor deposition (CVD) device. The CVD device has a form provided with a substrate support 11 and a shower head 15 in a deposition chamber 10 as illustrated schematically in FIG. 1.

As the shower head 15, a shower head made of a metal material and a shower head made of a ceramic material are largely used depending on a process to be used.

The shower head 15 generally has a shape as illustrated in FIG. 2. During gas injection, the shower head 15 heats and injects gas or injects the gas at room temperature according to a process, and in the case of heating and injecting the gas, as illustrated in FIG. 2, a heating wire 1 is installed around gas injection holes 2.

Specifically, the conventional shower head 15 consists of one gas inlet and multiple gas injection holes 2, and at this time, a distance between the centers of the gas injection holes 2 is 3 mm or less so as to uniformly inject the gas. Accordingly, in the case of arranging the heating wire 1 around the gas injection holes 2 to heat and inject the gas, since the diameter of the heating wire 1 is often larger than the distance between the gas injection holes 2, it is difficult to install the heating wire. In addition, in this situation, when the distance between the gas injection holes 2 is increased, there is a problem in that it is difficult to uniformly inject the gas.

Therefore, in order to solve the above problems, in the related art, a method of disposing the heating wire 1 outside the shower head where the gas injection holes 2 are not present has attempted. However, in this case, there is a problem in that the injected gas does not have a uniform temperature. Therefore, the above problem is recognized as a problem to be solved in the art.

In addition, since a conventional shower head made of a metal material reacts with a process gas, the life of the shower head is shortened due to corrosion, and a particle problem is caused due to desorption of reactants. In addition, there is a problem in that it is difficult to install an RF mesh layer that helps plasma generation so as to be used in a special process due to a current carrying problem. Therefore, urgent solutions to these problems have been required.

### PRIOR ARTS

[Patent Document]

Korean Patent Publication No. 10-2014-0011364

### DISCLOSURE

### Technical Problem

The present invention is derived to solve the problems in the related art, and an object of the present invention is to provide a shower head and a chemical vapor deposition (CVD) device including the same, in which a heating wire may be easily installed while a sufficient number of gas injection holes is provided for uniform injection of gas by changing a distribution structure of the gas.

Further, another object of the present invention is to provide a shower head and a chemical vapor deposition (CVD) device including same with significantly improved temperature uniformity of gas to be injected by changing a distribution structure of gas.

Further, yet another object of the present invention is to provide a shower head and a chemical vapor deposition (CVD) device including the same which is made of a ceramic material to improve durability, solve a particle problem due to desorption of reactants, and install an RF mesh without fear of current carrying.

Further, still another object of the present invention is to provide a shower head and a chemical vapor deposition (CVD) device including same in which processing is easier due to a structural change.

### Technical Solution

The present invention provides a shower head for a chemical vapor deposition system comprising:

a chamber; a process gas inlet for the chamber; a second gas distributor plate provided at the bottom of the chamber; and a first gas distributor plate stacked on the upper surface of the second gas distributor plate, wherein the first gas distributor plate includes multiple gas distribution holes, the second gas distributor plate includes multiple gas injection holes, and a distribution channel is arranged at the boundary surface between the first gas distributor plate and the second gas distributor plate so as to distribute a process gas, introduced through each gas distribution hole of the first gas distributor plate, to 2 to 8 gas injection holes of the second gas distributor plate.

In one embodiment of the present invention, a heating wire may be further provided between the gas distribution holes of the first gas distributor plate.

In one embodiment of the present invention, the distribution channel may be a linear type that connects each gas distribution hole and each of the 2 to 8 gas injection holes connected thereto through a separate channel; a surface type that connects each gas distribution hole and 2 to 8 gas injection holes connected thereto through one space; or a combination type of the linear type and the surface type.

In one embodiment of the present invention, the first gas distributor plate and the second gas distributor plate may be made of an aluminum nitride (AlN) sintered body.

In one embodiment of the present invention, the aluminum nitride (AlN) sintered body may include aluminum nitride (AlN), alumina (Al₂O₃), and rare earth metals.

In one embodiment of the present invention, the heating wire may be formed on an upper surface, a lower surface, or an interior of the first gas distributor plate.

In one embodiment of the present invention, the heating wire may be a wire member elongated in a longitudinal direction and made of a metal material, and may be wired two-dimensionally on a virtual two-dimensional plane parallel to the first gas distributor plate, or three-dimensionally wired in a virtual three-dimensional space.

In one embodiment of the present invention, an RF mesh layer for plasma generation may be further provided between the gas injection holes of the second gas distributor plate.

In one embodiment of the present invention, the RF mesh layer may be formed on an upper surface, a lower surface, or an interior of the second gas distributor plate.

In one embodiment of the present invention, the chemical vapor deposition system may be used for semiconductor manufacturing.

Further, the present invention provides a chemical vapor deposition device having the shower head of the present invention.

The chemical vapor deposition device may be used for semiconductor manufacturing.

### Advantageous Effects

The shower head of the present invention provides an effect of easily installing the heating wire while providing a sufficient number of gas injection holes for uniform injection of gas by changing a gas distribution structure.

In addition, the shower head of the present invention mixes well the heated air in the distribution channel according to the changed gas distribution structure to remarkably improve the temperature uniformity of the injection gas.

Further, the shower head of the present invention is made of a ceramic material to solve problems such as corrosion caused by reaction with gas, thereby improving durability, solving a particle problem caused by desorption of the reactants with gas, and installing an RF mesh without fear of current carrying.

In addition, although the shower head of the present invention needs to be processed to be divided into several layers due to a change in structure, processing for each layer is easy, thereby saving time and cost.

### DESCRIPTION OF DRAWINGS

FIG. 1 schematically illustrates a chemical vapor deposition (CVD) device in the related art.

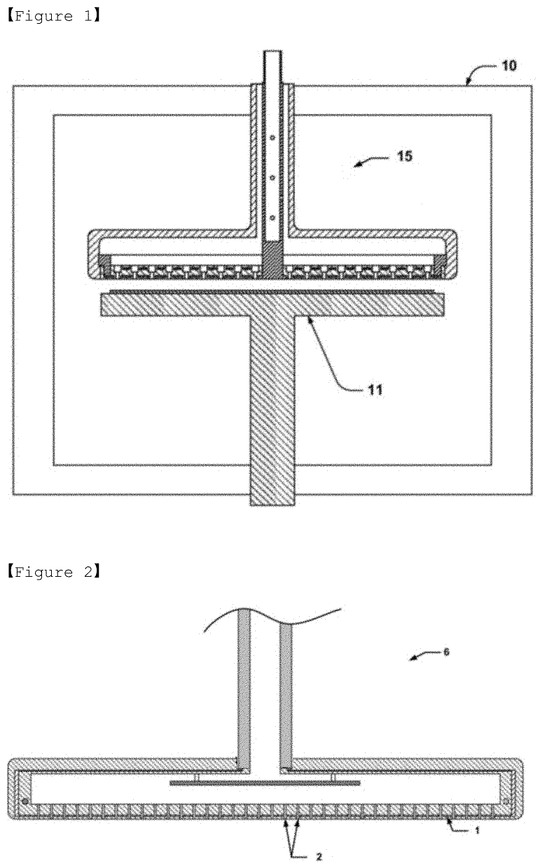

FIG. 2 schematically illustrates a shower head included in the chemical vapor deposition (CVD) device in the related art.

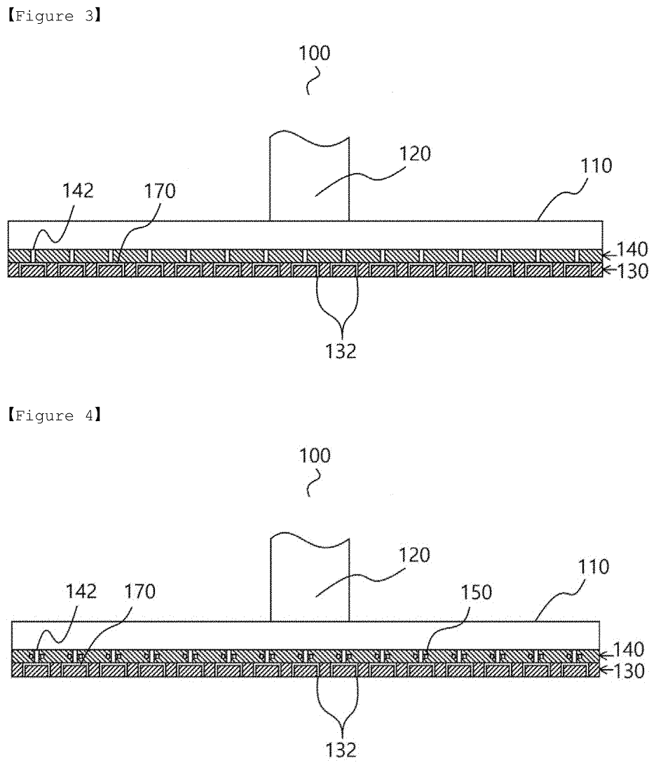

FIGS. 3 to 6 schematically illustrate a shower head of the present invention.

FIGS. 6 and 7 schematically illustrate a form of a distribution channel included in the shower head of the present invention.

FIG. 8 illustrates an exploded view of a first gas distributor plate and a second gas distributor plate of the shower head of the present invention.

FIG. 9 schematically illustrates a chemical vapor deposition (CVD) device of the present invention.

### BEST MODE

Hereinafter, the present invention will be described in detail so as to be easily implemented by those skilled in the art, with reference to the accompanying drawings. However, the present invention may be embodied in many different forms and are not limited to this specification.

In the drawings, parts not related with the description are omitted in order to clearly describe the present invention and throughout the specification, like reference numerals designate like parts. The sizes and relative sizes of components illustrated in the drawings are unrelated to an actual scale and will be reduced or exaggerated for clarity of description.

Terms and words used in the present specification and claims should not be interpreted as being limited to typical or dictionary meanings, but should be interpreted as meanings and concepts which comply with the technical spirit of the present invention, based on the principle that the present inventor can appropriately define the concepts of the terms to describe his/her own invention in the best manner.

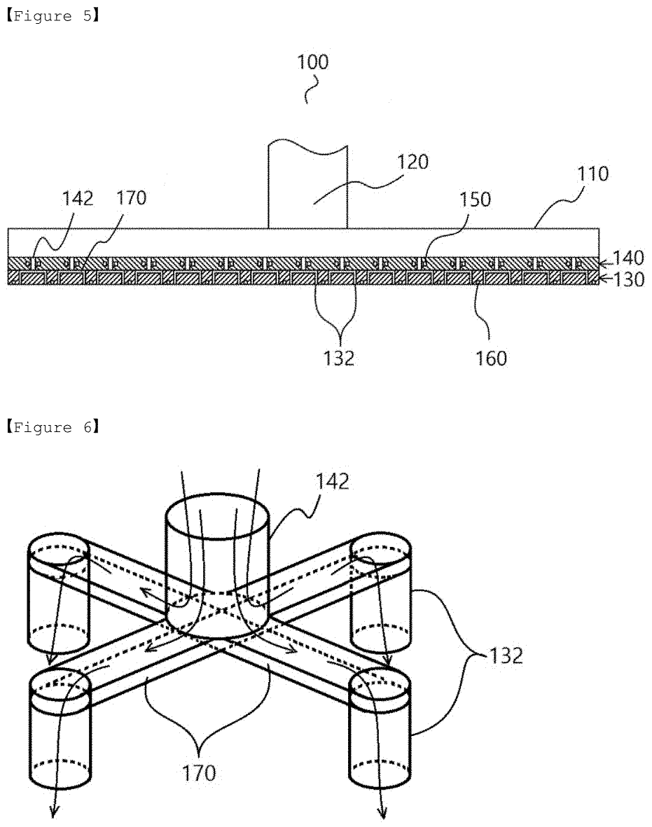

A shower head 100 of the present invention, as illustrated in FIGS. 3 and 4, comprises:

a chamber 110; a process gas inlet 120 for the chamber; a second gas distributor plate 130 provided at the bottom of the chamber; and a first gas distributor plate 140 stacked on the upper surface of the second gas distributor plate,

wherein the first gas distributor plate 140 includes multiple gas distribution holes 142, the second gas distributor plate 130 includes multiple gas injection holes 132, and a distribution channel 170 is provided at the boundary surface between the first gas distributor plate 140 and the second gas distributor plate 130 so as to distribute a process gas, introduced through each gas distribution hole 142 of the first gas distributor plate, to 2 to 8 gas injection holes 132 of the second gas distributor plate.

Hereinabove, it may be more preferable to distribute the process gas introduced into each of the gas distribution holes 142 to 4 to 8 gas injection holes 132.

In one embodiment of the present invention, as illustrated in FIG. 3, a heating wire may be further provided between the gas distribution holes of the first gas distributor plate.

In general, the shower head consists of one gas inlet and multiple gas injection holes, and at this time, a distance between the centers of the gas injection holes is designed to be very narrow with 3 mm or less so as to uniformly inject the gas. Accordingly, in the case of arranging the heating wire around the gas injection holes to heat and inject the gas, since the diameter of the heating wire is often larger than the distance between the gas injection holes, it is difficult to install the heating wire.

On the other hand, when the distance between the gas injection holes is increased, it is difficult to uniformly inject the gas.

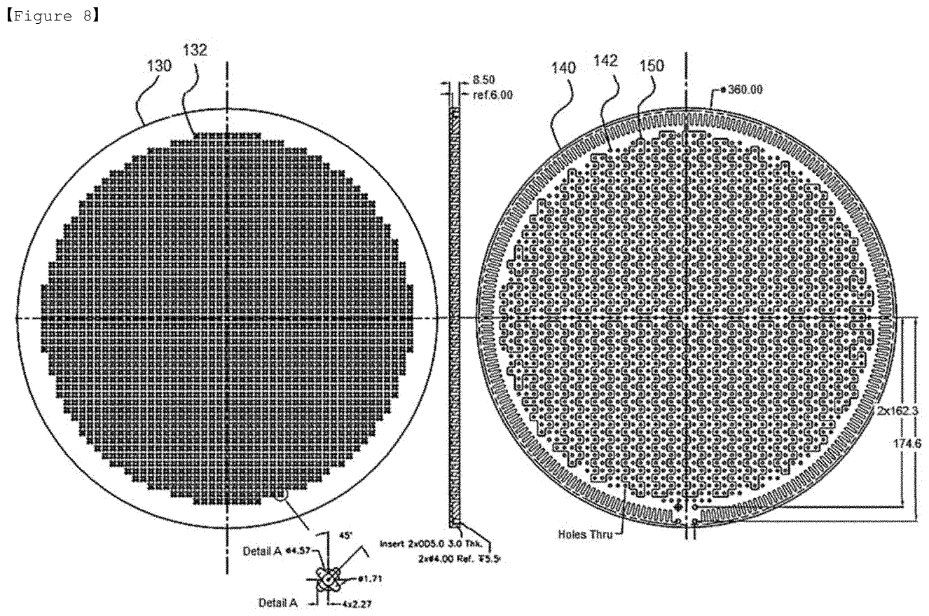

Accordingly, the shower head 100 of the present invention is characterized in that the problem is solved by changing the structure of the shower head as illustrated in FIGS. 3 to 8.

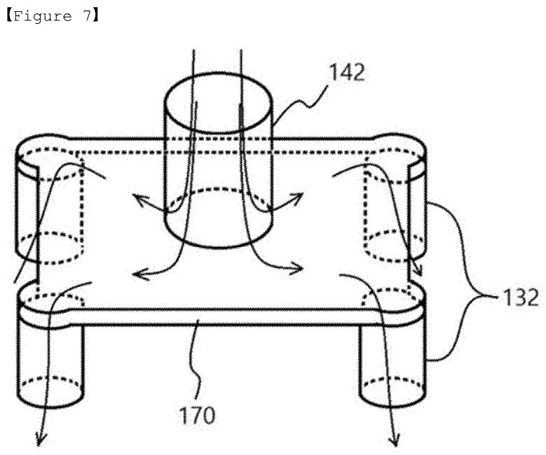

In the case of the change as described above, the air heated by the heating wire while passing through the gas distribution holes 142 of the gas distributor plate 140 is mixed well while passing through a distribution channel 170 (see FIGS. 6 and 7) separated into small units and then injected to the gas injection holes 132 of the gas distributor plate 130, thereby remarkably improving the temperature uniformity of the gas to be injected for deposition. When the distribution channel 170 is formed as illustrated in FIGS. 6 and 7, the vortex of the heated air does not occur due to the narrow space to form air having a uniform temperature.

In one embodiment of the present invention, as illustrated in FIG. 6, the distribution channel 170 may be a linear type that connects each gas distribution hole and each of the 2 to 8 gas injection holes connected thereto through a separate channel; a surface type that connects each gas distribution hole and 2 to 8 gas injection holes connected thereto through one space; or a combination type of the linear type and the surface type.

As illustrated in FIGS. 3 to 8, the shower head of the present invention needs to be processed to be divided into two plates due to a change in structure, but since the processing for each layer is easy, as a result, there is provided an effect of saving time and cost. That is, since it is easier to process each of the gas distribution holes and the gas injection holes in the first gas distributor plate and the second gas distributor plate than to process narrow and long holes in one thick plate, according to the present invention, it is possible to reduce the time and cost.

The first gas distributor plate and the second gas distributor plate may be made of a ceramic material, particularly, an aluminum nitride (AlN) sintered body.

The aluminum nitride (AlN) sintered body may include aluminum nitride (AlN), alumina (Al₂O₃), and rare earth metals.

In the shower head 100 of the present invention, the heating wire may be formed on the first gas distributor plate, as illustrated in FIGS. 4, 5 and 8. The heating wire may be formed on an upper surface, a lower surface, or an interior (referring to FIG. 4) of the gas distributor plate.

The heating wire is not particularly limited, but may be formed of a metal wire member elongated in a longitudinal direction.

In addition, the heating wire may be two-dimensionally wired on a virtual two-dimensional plane parallel to the first gas distributor plate, or three-dimensionally wired in a virtual three-dimensional space. An example of the three-dimensional shape may be a heating wire having a spiral spring shape.

The shower head 100 of the present invention may further include an RF mesh layer that helps plasma generation between the gas distribution holes of the second gas distributor plate. As illustrated in FIG. 5, the mesh layer may be formed inside the second gas distributor plate or on the upper or lower surface of the second gas distributor plate.

When the shower head (the second gas distributor plate) is made of a metal material as in the related art, the RF mesh layer cannot be installed due to a current carrying problem, but in the shower head of the present invention made of the ceramic material, it is possible to install the RF mesh layer.

In the present invention, the chemical vapor deposition system is not particularly limited, but may be preferably used for semiconductor manufacturing.

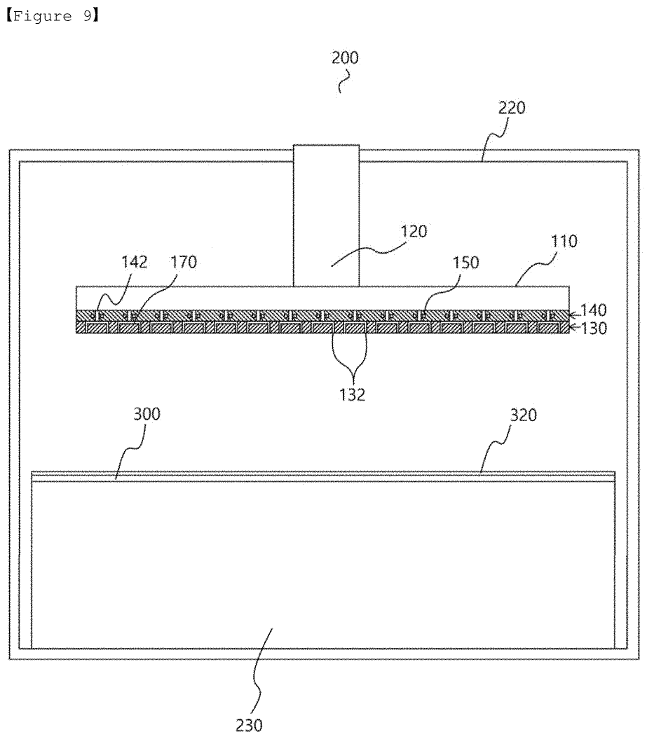

The present invention relates to a chemical vapor deposition (CVD) device including the shower head of the present invention. The chemical vapor deposition (CVD) device may have a form as illustrated in FIG. 9, and may include any form known in the art so long as the shower head of the present invention is provided.

The chemical vapor deposition device is not particularly limited, but may be preferably used for semiconductor manufacturing.

[Explanation of Reference Numerals and Symbols]

| | |
|---|---|
| 100: Shower head | 110: Chamber |
| 120: Process gas inlet | 130: Second gas distributor plate |
| 132: Gas injection hole | 140: First gas distributor plate |
| 142: Gas distribution hole | 150: Heating wire |
| 160: Plasma formation RF mesh | 170: Distribution channel |
| 200: Chemical vapor deposition device | 230: Substrate support |
| 220: Deposition chamber | 320: Deposition layer |
| 300: Substrate | |

1. A shower head for a chemical vapor deposition system comprising:
a chamber; a process gas inlet for the chamber; a second gas distributor plate provided at the bottom of the chamber; and a first gas distributor plate stacked on the upper surface of the second gas distributor plate,
wherein the first gas distributor plate includes multiple gas distribution holes, the second gas distributor plate includes multiple gas injection holes, and a distribution channel is arranged at the boundary surface between the first gas distributor plate and the second gas distributor plate so as to distribute a process gas, introduced through each gas distribution hole of the first gas distributor plate, to 2 to 8 gas injection holes of the second gas distributor plate.

2. Shower head for the chemical vapor deposition system of claim 1, wherein a heating wire is further provided between the gas distribution holes of the first gas distributor plate.

3. The shower head for the chemical vapor deposition system of claim 1, wherein the distribution channel is a linear type that connects each gas distribution hole and each of the 2 to 8 gas injection holes connected thereto through a separate channel; a surface type that connects each gas distribution hole and 2 to 8 gas injection holes connected thereto through one space; or a combination type of the linear type and the surface type.

4. Shower head for the chemical vapor deposition system of claim 1, wherein the first gas distributor plate and the second gas distributor plate are made of an aluminum nitride (AlN) sintered body.

5. The shower head for the chemical vapor deposition system of claim 4, wherein the aluminum nitride (AlN) sintered body includes aluminum nitride (AlN), alumina (Al₂O₃), and rare earth metals.

6. The shower head for the chemical vapor deposition system of claim 2, wherein the heating wire is formed on an upper surface, a lower surface, or an interior of the first gas distributor plate.

7. The shower head for the chemical vapor deposition system of claim 6, wherein the heating wire is a wire member elongated in a longitudinal direction and made of a metal material, and is wired two-dimensionally on a virtual two-dimensional plane parallel to the first gas distributor plate, or three-dimensionally wired in a virtual three-dimensional space.

8. The shower head for the chemical vapor deposition system of claim 1, wherein an RF mesh layer for plasma generation is further provided between the gas injection holes of the second gas distributor plate.

9. The shower head for the chemical vapor deposition system of claim 8, wherein the RF mesh layer is formed on an upper surface, a lower surface, or an interior of the second gas distributor plate.

10. The shower head for the chemical vapor deposition system of claim 1, wherein the chemical vapor deposition system is used for semiconductor manufacturing.

11. A chemical vapor deposition device having the shower head of claim 1.

12. The chemical vapor deposition device of claim 11, wherein the chemical vapor deposition device is used for semiconductor manufacturing.
